(19) United States
(12) Patent Application Publication
(10) Pub. No.: US 2023/0290792 A1
(43) Pub. Date: Sep. 14, 2023

(54) IMAGING DEVICE AND ELECTRONIC DEVICE

(71) Applicant: SONY SEMICONDUCTOR SOLUTIONS CORPORATION, KANAGAWA (JP)

(72) Inventor: TETSUYA YAMAGUCHI, KANAGAWA (JP)

(21) Appl. No.: 18/002,505

(22) PCT Filed: May 19, 2021
(86) PCT No.: PCT/JP2021/019021

§ 371 Date: Dec. 20, 2022

(30) Foreign Application Priority Data
Jun. 29, 2020 (JP) 2020-111664

(51) Int. Cl. H01L 27/146; G01S 17/08

(52) U.S. Cl. CPC H01L 27/1461; H01L 27/1462; H01L 27/14623; H01L 27/14627; H01L 27/1463; H01L 27/14634; H01L 27/14643; H01L 27/14685; H01L 27/14689; G01S 17/08

(57) ABSTRACT

Provided are an imaging device and an electronic device capable of suppressing deterioration in characteristic. An imaging device is provided with an N-type first semiconductor region, a P-type second semiconductor region in contact with one surface of the first semiconductor region, a light absorbing region provided on a side opposite to the first semiconductor region across the second semiconductor region, and an anode electrode provided at a position facing the second semiconductor region across the light absorbing region. The anode electrode includes a P-type semiconductor having a refractive index of 1.8 or larger and an optical bandgap of 1.9 eV or larger.

### TECHNICAL FIELD

The present disclosure relates to an imaging device and an electronic device.

### BACKGROUND ART

An imaging device using an avalanche photodiode is disclosed (refer to Patent Document 1).

### CITATION LIST

### Patent Document

Patent Document 1: Japanese Patent Application Laid-Open No. 2019-140132

### SUMMARY OF THE INVENTION

### Problems to be Solved by the Invention

An imaging device using an avalanche photodiode includes an N-type semiconductor region, a P-type semiconductor region provided closer to a light incident surface than this N-type semiconductor region, a light absorbing region (photoelectric conversion region) provided closer to the light incident surface than the P-type semiconductor region, and an anode electrode in contact with the light absorbing region. An avalanche amplification region is formed on a PN junction surface between the N-type semiconductor region and the P-type semiconductor region described above. Electrons generated by photoelectric conversion in the light absorbing region propagate to the avalanche amplification region and are subjected to avalanche amplification.

The anode electrode is formed by multistage ion implantation of P-type impurities at high acceleration into a semiconductor in a region adjacent to the light absorbing region (for example, an inter-pixel isolation region). In the ion implantation, since an implantation amount of impurities tends to vary in a depth direction of the implantation, it is difficult to form the anode electrode at a uniform impurity concentration. When the impurity concentration of the anode electrode is non-uniform, a resistance value of the anode electrode varies, and a characteristic of the imaging device might be deteriorated.

The present disclosure has been made in view of such circumstances, and an object thereof is to provide an imaging device and an electronic device capable of suppressing deterioration in characteristic.

### Solutions to Problems

An imaging device according to an aspect of the present disclosure is provided with an N-type first semiconductor region, a P-type second semiconductor region in contact with one surface of the first semiconductor region, a light absorbing region provided on a side opposite to the first semiconductor region across the second semiconductor region, and an anode electrode provided at a position facing the second semiconductor region across the light absorbing region. The anode electrode includes a P-type semiconductor having a refractive index of 1.8 or larger and an optical bandgap of 1.9 eV or larger.

With this arrangement, as the P-type semiconductor, for example, P-type amorphous silicon carbide (a-SiC), P-type polysilicon carbide (poly-SiC), P-type amorphous silicon nitride (a-SiN), or P-type polysilicon nitride (poly-SiN) may be used. Since these films may be formed by a chemical vapor deposition (CVD) method while being doped with P-type impurities such as boron (B) in situ, a P-type impurity concentration in the film may be made uniform or substantially uniform. Therefore, the imaging device may suppress variation in electric resistance of the anode electrode, so that this may suppress deterioration in characteristic (for example, variation in sensitivity among a plurality of pixels) due to this variation.

An electronic device according to an aspect of the present disclosure is provided with a light source that emits light of a wavelength band set in advance, and an imaging device that photoelectrically converts the light and outputs a signal. The imaging device is provided with an N-type first semiconductor region, a P-type second semiconductor region in contact with one surface of the first semiconductor region, a light absorbing region provided on a side opposite to the first semiconductor region across the second semiconductor region, and an anode electrode provided at a position facing the second semiconductor region across the light absorbing region. The anode electrode includes a P-type semiconductor having a refractive index of 1.8 or larger and an optical bandgap of 1.9 eV or larger.

With this arrangement, since the electronic device is provided with the above-described imaging device, so that this may suppress deterioration in characteristic due to variations in electric resistance of the anode electrode.

### BRIEF DESCRIPTION OF DRAWINGS

FIG. 1 is a cross-sectional view schematically depicting a configuration example of an imaging device according to a first embodiment of the present disclosure.

FIG. 2 is a graph depicting a result of simulation of a relationship between a film thickness H of a P-type amorphous silicon carbide (a-SiC) film used for an anode electrode and reflectance of infrared light on an incident surface side of a sensor substrate in the sensor substrate according to the first embodiment of the present disclosure.

FIG. 3 is a diagram depicting a configuration on the incident surface side of the sensor substrate set when the simulation of FIG. 2 is performed.

FIG. 4 is a graph depicting a result of simulation of a relationship between a wavelength of incident light and transmittance of the incident light to a Si substrate in the sensor substrate according to the first embodiment of the present disclosure.

FIG. 5 is a diagram depicting the configuration on the incident surface side of the sensor substrate set when the simulation of FIG. 4 is performed.

FIG. 6A is a cross-sectional schematic diagram depicting a method of manufacturing the imaging device according to the first embodiment of the present disclosure step by step.

FIG. 6B is a cross-sectional schematic diagram depicting the method of manufacturing the imaging device according to the first embodiment of the present disclosure step by step.

FIG. 6C is a cross-sectional schematic diagram depicting the method of manufacturing the imaging device according to the first embodiment of the present disclosure step by step.

FIG. 6D is a cross-sectional schematic diagram depicting the method of manufacturing the imaging device according to the first embodiment of the present disclosure step by step.

FIG. 6E is a cross-sectional schematic diagram depicting the method of manufacturing the imaging device according to the first embodiment of the present disclosure step by step.

FIG. 6F is a cross-sectional schematic diagram depicting the method of manufacturing the imaging device according to the first embodiment of the present disclosure step by step.

FIG. 6G is a cross-sectional schematic diagram depicting the method of manufacturing the imaging device according to the first embodiment of the present disclosure step by step.

FIG. 7 is a cross-sectional view schematically depicting a configuration of a sensor substrate according to a variation of the first embodiment of the present disclosure.

FIG. 8 is a cross-sectional view schematically depicting a configuration example of a sensor substrate according to a second embodiment of the present disclosure.

FIG. 9 is a plan view schematically depicting a configuration example of an imaging device according to a second embodiment of the present disclosure.

FIG. 10 is a cross-sectional view depicting a configuration example of the imaging device according to the second embodiment of the present disclosure.

FIG. 11 is a block diagram depicting a configuration example of a ranging device according to a third embodiment of the present disclosure.

FIG. 12 is a view depicting an example of a schematic configuration of an endoscopic surgery system.

FIG. 13 is a block diagram depicting an example of a functional configuration of a camera head and a camera control unit (CCU).

FIG. 14 is a block diagram depicting an example of schematic configuration of a vehicle control system.

FIG. 15 is a diagram of assistance in explaining an example of installation positions of an outside-vehicle information detecting section and an imaging section.

### MODE FOR CARRYING OUT THE INVENTION

Hereinafter, an embodiment of the present disclosure is described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it goes without saying that dimensional relationships and ratios are partly different between the drawings.

Definition of directions such as upward and downward directions in the following description is merely the definition for convenience of description, and does not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

In the following description, the direction is sometimes described using terms such as an X-axis direction, a Y-axis direction, and a Z-axis direction. For example, the X-axis direction and the Y-axis direction are directions parallel to a back surface 10b of a semiconductor substrate 10. The Z-axis direction is a direction perpendicular to the back surface 10b of the semiconductor substrate 10. The Z-axis direction is a thickness direction of the semiconductor substrate 10, and is also a thickness direction of a sensor substrate 1 including the semiconductor substrate 10. The X-axis direction, the Y-axis direction, and the Z-axis direction are orthogonal to each other.

In the following description, + or − is sometimes added as for P or N indicating a conductivity type of a semiconductor. A semiconductor region to which + or − is added means that an impurity concentration thereof is relatively higher or lower than that of the semiconductor region to which + or − is not added. However, even in the semiconductor regions to which the same P and P (or N and N) are added, it does not mean that the impurity concentrations of the semiconductor regions are exactly the same.

### First Embodiment

(Configuration Example)

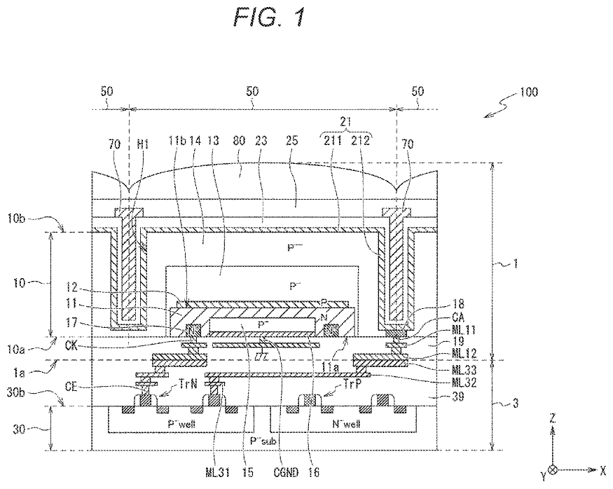

FIG. 1 is a cross-sectional view schematically depicting a configuration example of an imaging device 100 according to a first embodiment of the present disclosure. The imaging device 100 depicted in FIG. 1 is, for example, a back-illuminated solid-state imaging device. As depicted in FIG. 1, the imaging device 100 includes a sensor substrate 1 and a logic substrate 3 joined to a front surface 1a (in FIG. 1, a lower surface) side of the sensor substrate 1. Light to be detected by the sensor substrate 1 is, for example, infrared light, and a wavelength band thereof is of 900 nm or longer and 1100 nm or shorter.

The sensor substrate 1 includes a semiconductor substrate 10, a plurality of pixels 50 provided on the semiconductor substrate 10, a light-shielding electrode 70 (an example of a “light-shielding pixel isolation unit” of the present disclosure) provided on the semiconductor substrate 10, and a microlens 80 (an example of a “lens body” of the present disclosure) provided on a back surface 10b (in FIG. 1, an upper surface) side of the semiconductor substrate 10. The plurality of pixels 50 is arranged side by side in a direction parallel to the back surface 10b of the semiconductor substrate 10 (for example, in an X-axis direction and a Y-axis direction). The pixel 50 is, for example, an avalanche photodiode, a single photon avalanche diode (SPAD) as an example. The light-shielding electrode 70 is arranged in a region between adjacent pixels among the plurality of pixels 50. The light-shielding electrode 70 shields light between one pixel 50 and another pixel 50 adjacent to each other and isolates them from each other.

The semiconductor substrate 10 is, for example, a single-crystal silicon (Si) substrate. Alternatively, the semiconductor substrate 10 may be a single-crystal Si layer. The single-crystal Si layer may be obtained by, for example, forming a Si layer on a single-crystal support substrate not depicted by an epitaxial growth method and isolating the support substrate from the formed Si layer. The semiconductor substrate 10 is provided with an N-type first semiconductor region 11, a P-type second semiconductor region 12, a P⁻-type third semiconductor region 13, a P⁻⁻-type fourth semiconductor region 14, a P⁻-type fifth semiconductor region 15, a P⁺-type sixth semiconductor region 16, an N⁺-type seventh semiconductor region 17, and a P⁺-type eighth semiconductor region 18.

The P-type second semiconductor region 12 is arranged on one surface 11b (in FIG. 1, an upper surface) of the N-type first semiconductor region 11. The P-type second semiconductor region 12 is in contact with one surface 11b of the N-type first semiconductor region 11. A portion in which the first semiconductor region 11 and the second semiconductor region 12 are in contact with each other is a PN junction of the SPAD.

The P⁻-type third semiconductor region 13 is arranged on the P-type second semiconductor region 12, and the P⁻⁻-type fourth semiconductor region 14 is arranged on the P⁻-type third semiconductor region 13. The P⁻-type third semiconductor region 13 and the P⁻⁻-type fourth semiconductor region 14 are an example of a “light absorbing region” of the present disclosure. The P⁻-type third semiconductor region 13 is arranged so as to cover the N-type first semiconductor region 11 and the P-type second semiconductor region 12 from a light irradiation surface (for example, a back surface) side, and is in contact with each of the first semiconductor region 11 and the second semiconductor region 12. Furthermore, the P⁻⁻-type fourth semiconductor region 14 is arranged so as to cover the P⁻-type third semiconductor region 13 from the light irradiation surface side, and is in contact with the third semiconductor region 13.

P−P—The P⁻-type fifth semiconductor region 15 and the P⁺-type sixth semiconductor region 16 are arranged on the other surface 11a (in FIG. 1, a lower surface) side of the first semiconductor region 11. The P⁻-type fifth semiconductor region 15 is in contact with the other surface 11a of the N-type first semiconductor region 11. The P⁺-type sixth semiconductor region 16 faces a front surface 10a (in FIG. 1, a lower surface) of the semiconductor substrate 10. The fifth semiconductor region 15 is arranged between the first semiconductor region 11 and the sixth semiconductor region 16. The N⁺-type seventh semiconductor region 17 is provided on the other surface 11a side of the first semiconductor region 11 and is in contact with the front surface 10a (in FIG. 1, the lower surface) of the semiconductor substrate 10.

A magnitude relationship of an N-type impurity concentration between the first semiconductor region 11 and the seventh semiconductor region 17, and a P-type impurity concentration in each of the second semiconductor region 12, the third semiconductor region 13, the fourth semiconductor region 14, the fifth semiconductor region 15, and the sixth semiconductor region 16 is as indicated by a superscript of + or − as described above. That is, the N-type impurity concentration is higher in the N⁺-type seventh semiconductor region 17 than in the N-type first semiconductor region 11. The P-type impurity concentration is lower in the P⁻-type third semiconductor region 13 than in the P-type second semiconductor region, and the P-type impurity concentration is lower in the P⁻⁻-type fourth semiconductor region 14 than in the P⁻-type third semiconductor region 13.

Note that, the P⁻⁻-type fourth semiconductor region 14 may be an intrinsic semiconductor region (of i-type). Furthermore, the third semiconductor region 13 and the fourth semiconductor region 14 may include one semiconductor region a conductivity type of which is the P-type or P⁻-type. That is, the “light absorbing region” of the present disclosure may include one semiconductor region the conductivity type of which is the P-type or P⁻-type.

Furthermore, the sensor substrate 1 includes an anode electrode 21 and a first insulating film 23 (an example of an “insulating film” of the present disclosure) and a second insulating film 25 provided on a side opposite to the light absorbing region across the anode electrode 21. In the semiconductor substrate 10, a trench H1 is formed from the back surface 10b to the front surface 10a side in a region between the adjacent pixels. The anode electrode 21 is provided continuously from the back surface 10b of the semiconductor substrate 10 to an inner side surface and a bottom surface of the trench H1.

For example, the anode electrode 21 includes a first site 211 arranged on the back surface 10b of the semiconductor substrate 10 and a second site 212 arranged in the trench H1. The first site 211 is in contact with the P⁻⁻-type fourth semiconductor region 14 in a Z-axis direction. The second site 212 faces the second semiconductor region 12 in the X-axis direction and the Y-axis direction intersecting with (for example, orthogonal to) the Z-axis direction, and is in contact with the P⁻⁻-type fourth semiconductor region 14. The second site 212 is in contact with the P⁻⁻-type fourth semiconductor region 14 on the inner side surface of the trench H1, and is in contact with the P⁺-type eighth semiconductor region 18 on the bottom surface of the trench H1.

The anode electrode 21 includes a P-type semiconductor having a refractive index of 1.8 or larger and an optical bandgap of 1.9 eV or larger. As such P-type semiconductor, P-type amorphous silicon carbide (a-SiC), P-type polysilicon carbide (poly-SiC), P-type amorphous silicon nitride (a-SiN), or P-type polysilicon nitride (poly-SiN) are exemplified. Furthermore, boron (B) is exemplified as the P-type impurities contained in the anode electrode 21. In order to lower resistivity of the anode electrode 21, a boron concentration in the anode electrode 21 (or a boron concentration in a-SiN) is preferably 1×10¹⁸ cm⁻³ or longer.

Since the anode electrode 21 includes the P-type semiconductor, this also serves as a hole accumulation layer. The hole accumulation layer may cause electrons present at an interface between this hole accumulation layer and another layer (for example, the fourth semiconductor region 14 or the first insulating film 23) to disappear by recombination, and may suppress a dark current caused by the electrons present at the interface.

The first insulating film 23 is provided continuously from the back surface 10b of the semiconductor substrate 10 to the inner side surface and the bottom surface of the trench H1 so as to cover the anode electrode 21. The first insulating film 23 is in contact with the anode electrode 21. The light-shielding electrode 70 is arranged in the trench H1 covered with the anode electrode 21 and the first insulating film 23, and is in contact with the first insulating film 23. The light-shielding electrode 70 is connected to, for example, a wire having the same potential as that of the anode electrode 21. The second insulating film 25 is provided on the back surface 10b side of the semiconductor substrate 10, and covers the first insulating film 23 and the light-shielding electrode 70. The microlens 80 is provided on a side opposite to the light absorbing region across the first insulating film 23 in a thickness direction of the light absorbing region (for example, in the Z-axis direction). For example, the microlens 80 is provided on the second insulating film 25. In the imaging device 100, a side on which the microlens 80 is provided is a light incident surface side.

The first insulating film 23 preferably includes a material having a refractive index smaller than that of the P-type semiconductor (for example, a P-type a-SiC film, a P-type poly-SiC film, a P-type a-SiN film, or a P-type poly-SiN film) forming the anode electrode 21. For example, the first insulating film 23 includes an aluminum oxide film (Al₂O₃ film), a silicon oxide film (SiO₂ film), or a hafnium oxide film (HfO₂ film). While a refractive index n of the P-type a-SiC film is about 2.6, the refractive index n of the Al₂O₃ film is about 1.76, the refractive index n of the SiO₂ film is about 1.46, and the refractive index of the HfO₂ film is about 1.9. Since the magnitude relationship of the refractive index is defined between the first insulating film 23 and the anode electrode 21 in this manner, it is possible to suppress reflection of the incident light on the sensor substrate 1 at the interface between the first insulating film 23 and the anode electrode 21.

Note that, in a case where the first insulating film 23 includes the Al₂O₃ film or the HfO₂ film, the first insulating film 23 also serves as a negative fixed charge film. The negative fixed charge film may trap electrons present at an interface between this negative fixed charge film and another layer (for example, the anode electrode 21 or the second insulating film), and may suppress a dark current caused by the electrons present at the interface. Since the Al₂O₃ film and the HfO₂ film have a stronger function as the negative fixed charge film than that of the SiO₂ film, it is more preferable to use the Al₂O₃ film or the HfO₂ film for the first insulating film 23. Therefore, the function as the hole accumulation layer of the anode electrode 21 may be further reinforced.

The second insulating film 25 preferably includes a material having the same refractive index as that of the first insulating film 23 or a material having a smaller refractive index than that of the first insulating film 23. For example, the second insulating film 25 includes a SiO₂ film. This makes it possible to suppress the reflection of the incident light on the sensor substrate 1 at the interface between the second insulating film 25 and the first insulating film 23.

The N-type first semiconductor region 11, the P-type second semiconductor region 12, the P⁻-type third semiconductor region 13, the P⁻⁻-type fourth semiconductor region 14, the P⁻-type fifth semiconductor region 15, the P⁺-type sixth semiconductor region 16, the N⁺-type seventh semiconductor region 17, the P+-type eighth semiconductor region 18, the anode electrode 21, the first insulating film 23, the second insulating film 25, and the microlens 80 are arranged in each of the plurality of pixels 50.

The P⁻-type third semiconductor region 13 and the P⁻⁻-type (or i-type) fourth semiconductor region 14 serve as the light absorbing region (photoelectric conversion region) of the SPAD. The P⁺-type sixth semiconductor region 16 serves as a region for ohmic connection of the P-type fifth semiconductor region 15 to a contact electrode CGND to be described later. The P⁺-type eighth semiconductor region 18 serves as a region for ohmic connection of the anode electrode 21 to a contact electrode CA to be described later. The N-type first semiconductor region 11 serves as a cathode. The N⁺-type seventh semiconductor region 17 serves as a region for ohmic connection of the N-type first semiconductor region 11 to a contact electrode CK to be described later.

When a voltage for electron amplification is applied between the first semiconductor region 11 (that is, the cathode) and the anode electrode 21, electrons generated in the light absorbing region by photoelectric conversion are accelerated toward the P-type second semiconductor region 12, and are subjected to avalanche amplification at the PN junction. The voltage for electron amplification is, for example, a voltage higher than a breakdown voltage of the PN junction between the N-type first semiconductor region 11 and the P-type second semiconductor region 12. Therefore, the electrons generated in the light absorbing region of the SPAD increase by many times at the PN junction. Therefore, the sensor substrate 1 may detect, for example, one photon for each pixel 50.

Furthermore, the sensor substrate 1 includes the contact electrodes CA, CK, and CGND provided on the front surface 10a side of the semiconductor substrate 10, a plurality of wiring layers ML11 and ML12, and an interlayer insulating film 19 covering the front surface 10a of the semiconductor substrate 10. One end of the contact electrode CA is in contact with the anode electrode 21, and the other end thereof is in contact with the wiring layer ML11 having a first potential (for example, a negative potential). One end of the contact electrode CK is in contact with the seventh semiconductor region 17, and the other end thereof is in contact with the wiring layer ML11 having a second potential (for example, a positive potential) higher than the first potential. One end of the contact electrode CGND is in contact with the sixth semiconductor region 16, and the other end thereof is in contact with the wiring layer ML11 having a reference potential (for example, a ground potential (0 V)). The contact electrodes CA, CK, and CGND include metal such as aluminum (Al) or tungsten (W), for example. The wiring layers ML11 and ML12 include metal such as copper (Cu), for example.

The logic substrate 3 includes a semiconductor substrate 30, an N-channel MOS transistor TrN provided on a front surface 30a (in FIG. 1, an upper surface) side of the semiconductor substrate 30, a P-channel MOS transistor TrP provided on the front surface 30a side of the semiconductor substrate 30, a plurality of wiring layers ML31, ML32, and ML33 provided on the front surface 30a side of the semiconductor substrate 30, a contact electrode CE connecting the MOS transistors TrN and TrP to the wiring layer ML31, and an interlayer insulating film 39 covering the front surface 30a of the semiconductor substrate 30. Furthermore, although not depicted, the logic substrate 3 includes an insulating isolation layer provided on the semiconductor substrate 30. The insulating isolation layer electrically isolates an element such as the MOS transistor TrN from another element.

The MOS transistors TrN and TrP, the wiring layers ML31, ML32, and ML33, and the like provided in the logic substrate 3 form a bias circuit that applies a voltage between the first semiconductor region 11 (cathode) of the SPAD and the anode electrode 21, an arithmetic circuit that performs arithmetic processing on the basis of a signal output from the SPAD, and the like.

In the sensor substrate 1, the wiring layer ML12 located on a side the closest to the surface is exposed from the interlayer insulating film 19. In the logic substrate 3, the wiring layer ML33 located on a side the closest to the surface is exposed from the interlayer insulating film 39. Each of the wiring layers ML12 and ML33 may be referred to as a pad electrode. The wiring layers ML12 and ML33 are provided at positions facing each other in the Z-axis direction, and are joined to each other (for example, Cu—Cu junction). Therefore, the sensor substrate 1 and the logic substrate 3 are joined to be integrated with each other, and it is possible to transmit and receive signals and apply a bias between the sensor substrate 1 and the logic substrate 3.

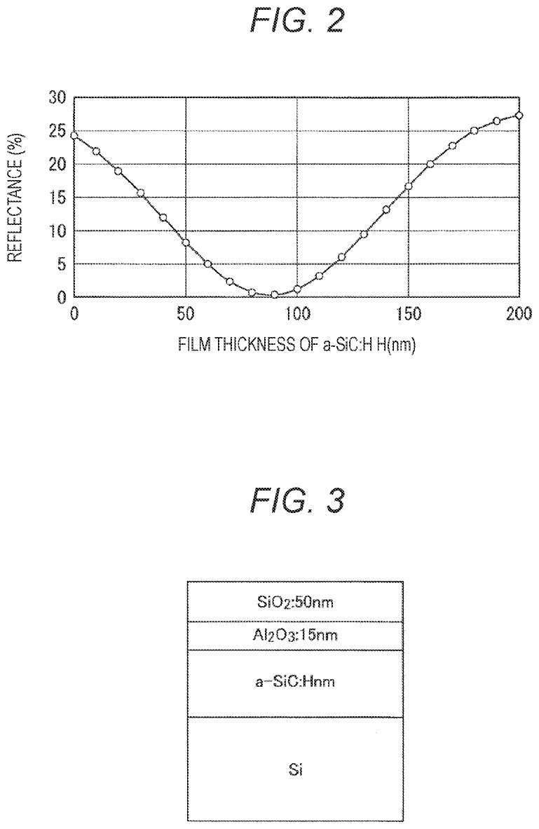

FIG. 2 is a graph depicting a result of simulation of a relationship between a film thickness H of the P-type amorphous silicon carbide (a-SiC) film used for the anode electrode 21 and reflectance of infrared light on the incident surface side of the sensor substrate 1 in the sensor substrate 1 according to the first embodiment of the present disclosure. In FIG. 2, the film thickness H of the P-type a-SiC film is plotted along the abscissa, and reflectance (%) is plotted along the ordinate. FIG. 3 is a diagram depicting a configuration on the incident surface side of the sensor substrate 1 set when the simulation of FIG. 2 is performed. As depicted in FIG. 3, in this simulation, a stacked body obtained by stacking a P-type a-SiC film (film thickness of H nm), an Al₂O₃ film (film thickness of 15 nm), and a SiO₂ film (film thickness of 50 nm) in this order on a Si substrate was made the configuration on the incident surface side of the sensor substrate 1. Light is incident on the Si substrate from the SiO₂ film. Furthermore, a wavelength of the infrared light in this simulation was set to 905 nm.

As is understood from FIG. 2, in a case where the light to be detected by the sensor substrate 1 is the infrared light, the film thickness of the P-type a-SiC film used for the anode electrode 21 is preferably 50 nm or more and 130 nm or less, more preferably 70 nm or more and 110 nm or less, and still more preferably about 90 nm. When the film thickness of the P-type a-SiC film used for the anode electrode 21 is within the above-described range, the reflectance of the infrared light on the incident surface side of the sensor substrate 1 may be kept low.

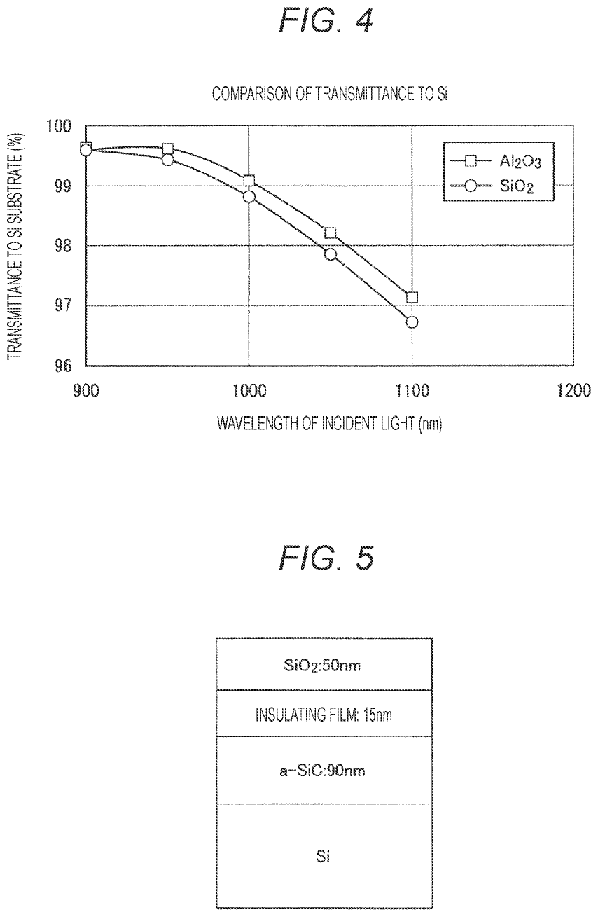

FIG. 4 is a graph depicting a result of simulation of a relationship between a wavelength of the incident light and transmittance of the incident light to the Si substrate in the sensor substrate 1 according to the first embodiment of the present disclosure. In FIG. 4, the wavelength of the incident light is plotted along the abscissa, and the transmittance (%) to the Si substrate is plotted along the ordinate. FIG. 5 is a diagram depicting the configuration on the incident surface side of the sensor substrate 1 set when the simulation of FIG. 4 is performed. As depicted in FIG. 5, in this simulation, a stacked body obtained by stacking a P-type a-SiC film (film thickness of 90 nm), an insulating film (film thickness of 15 nm), and a SiO₂ film (film thickness of 50 nm) in this order on a Si substrate was made the configuration on the incident surface side of the sensor substrate 1. Light is incident on the Si substrate from the SiO₂ film. Furthermore, in this simulation, two types of films, which are the Al₂O₃ film and the SiO₂ film, were set as depicted in FIG. 4 as the insulating film depicted in FIG. 5. In a case where the insulating film depicted in FIG. 5 is the SiO₂ film, the stacked body depicted in FIG. 5 has the configuration in which the SiO₂ film having a thickness of 65 nm (=15 nm+50 nm) is stacked on the SiC film.

As is understood from FIG. 4, when the wavelength of the incident light is 900 nm or longer and 1100 nm or shorter, the transmittance of the incident light to the Si substrate is 96% or larger. It may be said that the a-SiC film, the insulating film, and the SiO₂ film covering the Si substrate have high transmittance with respect to the incident light of the above-described wavelength. Furthermore, the transmittance of the insulating film between the a-SiC film and the SiO₂ film is slightly higher in a case where a film type is the Al₂O₃ film than in a case where the film type is the SiO₂ film. This difference in transmittance is substantially zero in a case where the wavelength of the incident light is 900 nm, and becomes slightly larger when the wavelength of the incident light becomes longer than 900 nm. The difference in transmittance is slight.

(Method of Manufacturing)

Next, an example of a method of manufacturing the imaging device 100 according to the first embodiment of the present disclosure is described. The imaging device 100 is manufactured using various types of devices such as a film forming device (including a CVD device, a thermal oxidation furnace, a sputtering device, and a resist applying device), an exposure device, an ion implantation device, an annealing device, an etching device, a chemical mechanical polishing (CMP) device, and a bonding device. Hereinafter, these devices are collectively referred to as manufacturing devices.

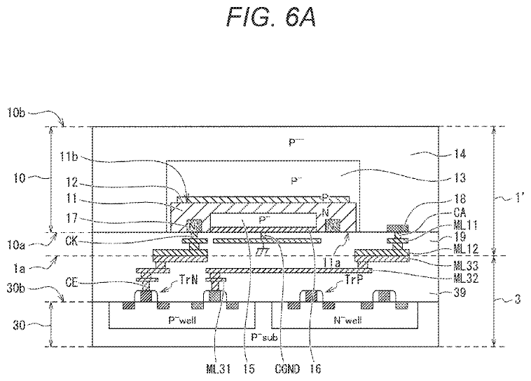

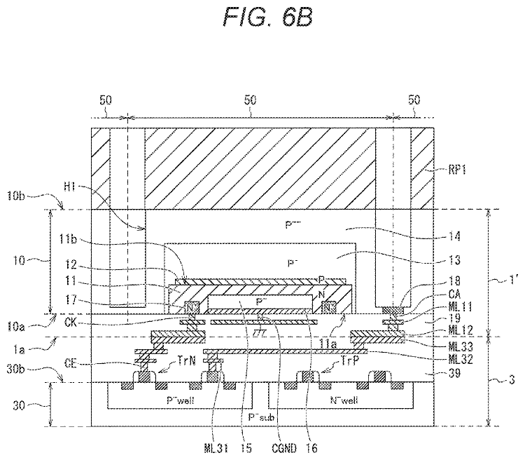

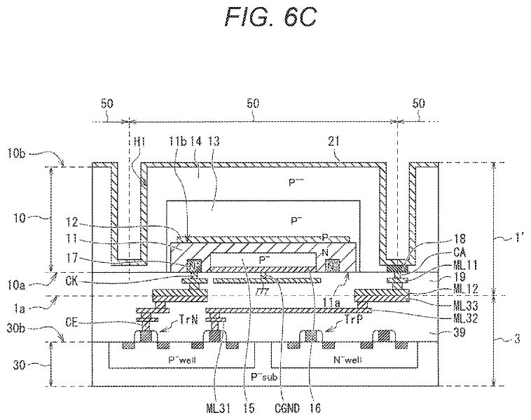

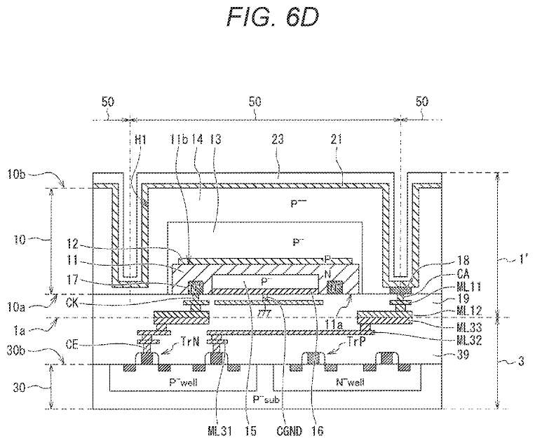

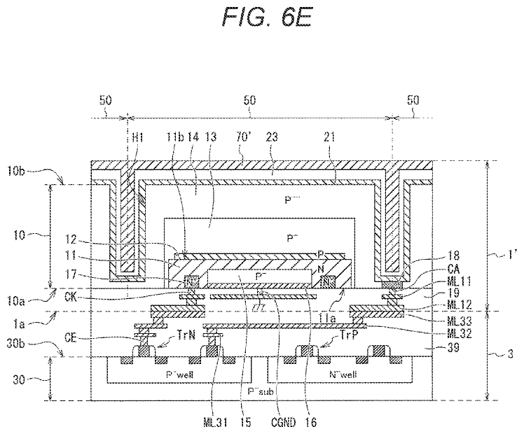

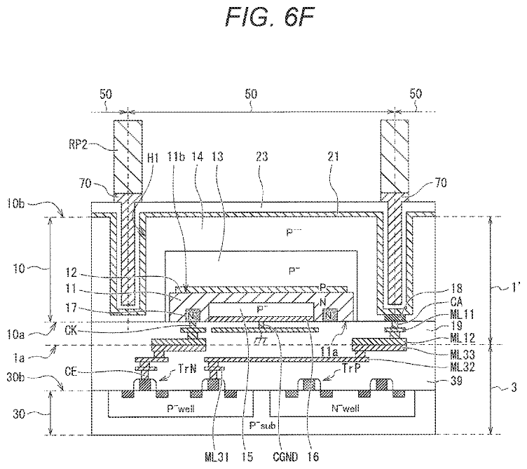

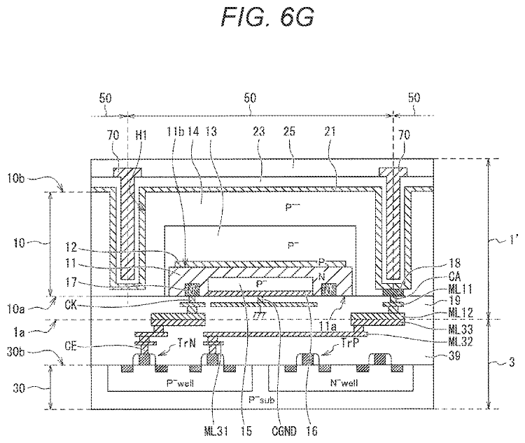

FIGS. 6A to 6G are cross-sectional schematic diagrams depicting the method of manufacturing the imaging device 100 according to the first embodiment of the present disclosure step by step. In FIG. 6A, the manufacturing device separately manufactures a sensor substrate 1′ and the logic substrate 3 using a CMOS process. For example, the manufacturing device forms the N-type first semiconductor region 11, the P-type second semiconductor region 12, the P⁻-type third semiconductor region 13, the P⁻⁻-type fourth semiconductor region 14, the P⁻-type fifth semiconductor region 15, the P⁺-type sixth semiconductor region 16, the N⁺-type seventh semiconductor region 17, and the P⁺-type eighth semiconductor region 18 in the semiconductor substrate 10 by sequentially performing ion implantation of the P-type impurities and N-type impurities from the front surface 10a side of the semiconductor substrate 10 into the semiconductor substrate 10 and performing thermal diffusion. Next, the manufacturing device forms the contact electrodes CA, CK, and CGND, the plurality of wiring layers ML11 and ML12, and the interlayer insulating film 19. The interlayer insulating film 19 is formed in a plurality of times so as to be interposed between the wiring layers ML11 and ML12. Therefore, the sensor substrate 1′ is manufactured.

Furthermore, the manufacturing device forms the insulating isolation layer not depicted, the N-channel MOS transistor TrN, and the P-channel MOS transistor TrP on the semiconductor substrate 30, and thereafter forms the contact electrode CE, the plurality of wiring layers ML31, ML32, and ML33, and the interlayer insulating film 39. The interlayer insulating film 39 is formed in a plurality of layers so as to be interposed between the wiring layers ML31, ML32, and ML33. Therefore, the logic substrate 3 is manufactured.

Next, the manufacturing device allows a surface of the sensor substrate 1′ and a surface of the logic substrate 3 to face each other to be joined. At this step, the wiring layer M12 of the sensor substrate 1′ and the wiring layer ML33 of the logic substrate 3 are joined by Cu—Cu junction, and the interlayer insulating film 19 of the sensor substrate 1′ and the interlayer insulating film 39 of the logic substrate 3 are put into close contact to be joined. Therefore, the sensor substrate 1′ and the logic substrate 3 are integrated with each other. Next, the manufacturing device grinds the back surface 10b side of the semiconductor substrate 10 to set a thickness of the semiconductor substrate 10 to a value set in advance.

Next, as depicted in FIG. 6B, the manufacturing device forms a resist pattern RP1 on the back surface 10b (in FIG. 6B, an upper surface) of the semiconductor substrate 10. The resist pattern RP1 has a shape that opens on a region between the pixels 50 and covers other regions. Next, the manufacturing device performs etching on the semiconductor substrate 10 using the resist pattern RP1 as a mask. This etching is performed by, for example, reactive ion etching (RIE). Therefore, the trench H1 is formed in the region between the pixels 50 in the semiconductor substrate 10. Thereafter, the manufacturing device removes the resist pattern RP1.

Next, as depicted in FIG. 6C, the manufacturing device forms the anode electrode 21 on the back surface 10b of the semiconductor substrate 10 using the CVD method and the like. The anode electrode 21 is formed continuously from the back surface 10b of the semiconductor substrate 10 to the inner side surface and the bottom surface of the trench H1. For example, the anode electrode 21 is, for example, the P-type a-SiC film, the P-type poly-SiC film, the P-type a-SiN film, or the P-type poly-SiN film, with the film thickness of 90 nm.

The P-type a-SiC film or the P-type poly-SiC film may be formed by a plasma CVD method using silane (SiH₄), methane (CH₄), diborane (B₂H₆), and hydrogen (H₂) as raw material gases. The P-type a-SiN film or the P-type poly-SiN film may be formed by a plasma CVD method using silane (SiH₄), ammonium (NH₃), diborane (B₂H₆), and hydrogen (H₂) as raw material gases. Diborane (B₂H₆) is used as a doping gas of P-type impurities when the a-SiC film or a-SiN film is formed. When a B₂H₆ gas flow rate increases, the P-type impurity concentration in the film increases and resistivity of the film decreases. Furthermore, when a H₂ gas flow rate increases, a poly film (polycrystalline film) is easily formed.

For example, the P-type a-SiC film is deposited by the plasma CVD method under conditions of the gas flow rate of SiH₄=10 sccm, CH₄=20 sccm, H₂=30 sccm, and B₂H₆/H₂=80 sccm (2600 ppm), a pressure in a chamber of 1 Torr, substrate temperature of 240° C., and RF power of 50 W. Note that, each condition of the gas flow rate, the pressure, the temperature, and the RF Power described above is merely an example, and these values may be appropriately changed by the CVD device.

The P-type a-SiC may be formed by a low-temperature process at about 240° C. Therefore, when the anode electrode 21 is formed, a thermal history loaded on the already formed N-type semiconductor region, P-type semiconductor region, and wiring layer may be kept small, and thermal diffusion of impurities and melting of the wiring layer may be suppressed. Therefore, it is possible to suppress fluctuation in characteristic due to the thermal history in the P-type semiconductor region, the N-type semiconductor region, and the wiring layer.

Next, as depicted in FIG. 6D, the manufacturing device forms the first insulating film 23 on the back surface 10b side of the semiconductor substrate 10 using the CVD method, the PVD method or the like. The anode electrode 21 is covered with the first insulating film 23. Next, as depicted in FIG. 6E, the manufacturing device forms a metal film 70′ having a light-shielding property on the back surface 10b side of the semiconductor substrate 10 using the CVD method, a sputtering method, or the like, and fills the trench H1. The metal film 70′ is tungsten (W), for example. Next, as depicted in FIG. 6F, the manufacturing device forms a resist pattern RP2 on the metal film 70′. The resist pattern RP2 has a shape that covers the region between the adjacent pixels 50 and exposes other regions, for example. Next, the manufacturing device performs etching on the metal film 70′ using the resist pattern RP2 as a mask. Therefore, as depicted in FIG. 6G, the light-shielding electrode 70 includes the metal film 70′. Thereafter, the manufacturing device removes the resist pattern RP2.

Next, the manufacturing device forms the second insulating film 25 on the back surface 10b side of the semiconductor substrate 10 using the CVD method, the PVD method, and the like. A thickness of the second insulating film 25 is, for example, 50 nm. Next, the manufacturing device attaches the microlens 80 (refer to FIG. 1) on the second insulating film 25. Through the above-described steps, the imaging device 100 depicted in FIG. 1 is completed.

### Effect of First Embodiment

As described above, the imaging device 100 according to the first embodiment of the present disclosure includes the N-type first semiconductor region 11, the P-type second semiconductor region 12 in contact with one surface 11b of the first semiconductor region 11, the light absorbing region (the third semiconductor region 13 and the fourth semiconductor region 14) provided on the side opposite to the first semiconductor region 11 across the second semiconductor region 12, and the anode electrode 21 provided at the position facing the second semiconductor region 12 across the light absorbing region. The anode electrode 21 includes the P-type semiconductor having the refractive index of 1.8 or larger and the optical bandgap of 1.9 eV or larger.

With this arrangement, as the P-type semiconductor, for example, P-type amorphous silicon carbide (a-SiC), P-type polysilicon carbide (poly-SiC), P-type amorphous silicon nitride (a-SiN), or P-type polysilicon nitride (poly-SiN) may be used. Since these films may be formed by a chemical vapor deposition (CVD) method while being doped with P-type impurities such as boron (B) in situ, the P-type impurity concentration in the film may be made uniform or substantially uniform, and the composition and crystal structure of the film may be easily homogenized. Therefore, the imaging device 100 may suppress variation in electric resistance (for example, resistivity) of the anode electrode 21, so that this may suppress deterioration in characteristic (for example, variation in sensitivity among a plurality of pixels) due to this variation.

Furthermore, the P-type a-SiC is a wide gap material (for example, Eg=1.9 eV or larger and 2.1 eV or shorter) and hardly absorbs infrared light. The P-type poly-SiC, P-type a-SiN, or P-type poly-SiN is also a wide gap material and hardly absorbs infrared light. Therefore, the light absorbing region may be made thick. Photoelectric conversion efficiency of the pixel 50 may be enhanced as the light absorbing region is thicker, so that the sensitivity of the pixel 50 may be improved.

Furthermore, by forming the anode electrode 21 by the CVD method, it is easy to form the second site 212 of the anode electrode 21 to have a narrow electrode width and to be deeper in the Z-axis direction as compared with a case where multistage ion implantation is performed at high acceleration. Since it is easy to form the anode electrode 21 deep in the Z-axis direction, the light absorbing region of the semiconductor substrate 10 may be made thick. The photoelectric conversion efficiency of the pixel 50 may be enhanced as the light absorbing region is thicker, so that the sensitivity of the pixel 50 may be further improved.

Furthermore, the P-type impurities such as boron (B) contained in the anode electrode 21 are doped in situ at the time of film formation. Therefore, an annealing step for activating the P-type impurities is unnecessary as compared with a case of performing the ion implantation of the P-type impurities, so that the number of manufacturing steps may be reduced and the step may be simplified.

Furthermore, the anode electrode 21 is formed at a back surface processing step after forming the wiring layers ML11, ML12, and ML31 to ML33 and bonding the semiconductor substrates 10 and 30 to each other as described above. A thermal history when forming the N-type semiconductor region and the P-type semiconductor region, a thermal history when forming the wiring layers ML11, ML12, and ML31 to ML33, and a thermal history when joining the semiconductor substrates 10 and 30 are not loaded on the anode electrode 21. Therefore, it is possible to suppress fluctuation in characteristic due to the thermal history as for the anode electrode 21.

(Variation)

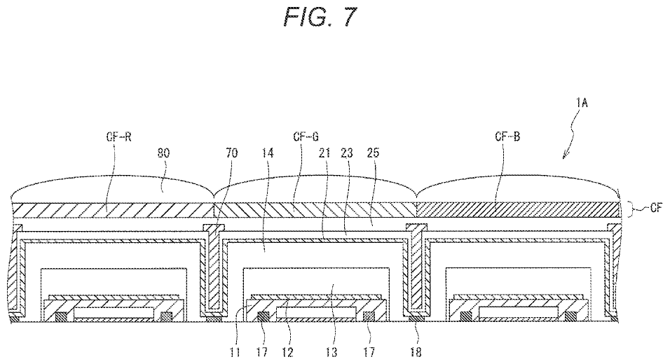

FIG. 7 is a cross-sectional view schematically depicting a configuration of a sensor substrate 1A according to a variation of the first embodiment of the present disclosure. As depicted in FIG. 7, the sensor substrate 1A includes a color filter CF between a second insulating film 25 and a microlens 80. The color filter CF includes, for example, a red filter CF-R, a green filter CF-G, and a blue filter CF-B. Any one of the red filter CF-R, the green filter CF-G, and the blue filter CF-B is arranged in each of a plurality of pixels 50.

With such a configuration, for example, P-type a-SiC, P-type poly-SiC, P-type a-SiN, or P-type poly-SiN may be used as an anode electrode 21. They may be formed by a CVD method, and a P-type impurity concentration in the film may be made uniform or substantially uniform. Therefore, an imaging device including the sensor substrate 1A has an effect similar to that of the first embodiment described above. Furthermore, since the sensor substrate 1A includes the color filter CF, the imaging device including the sensor substrate 1A may output a color image signal.

### Second Embodiment

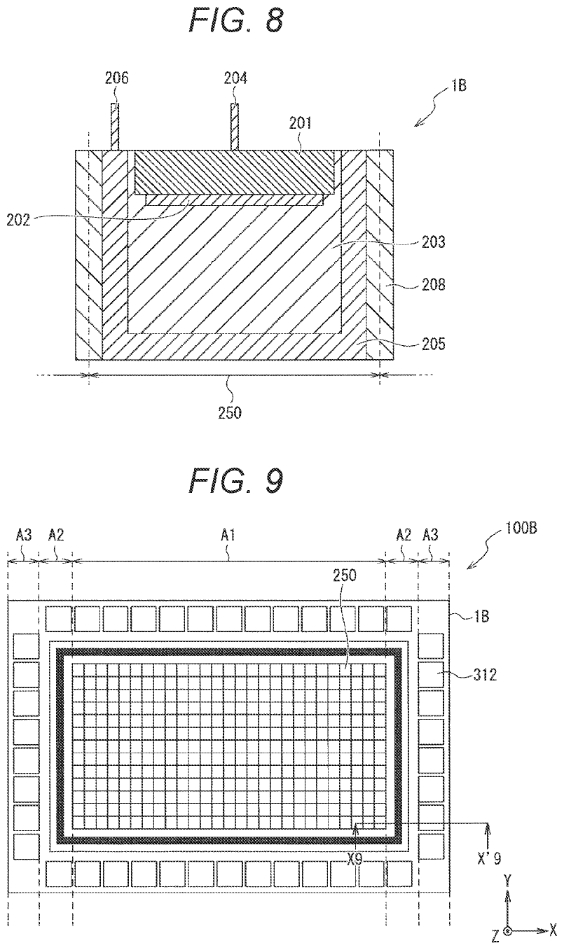

FIG. 8 is a cross-sectional view schematically depicting a configuration example of a sensor substrate 1B according to a second embodiment of the present disclosure. The sensor substrate 1B depicted in FIG. 8 includes a plurality of pixels 250. Each of the plurality of pixels 250 is, for example, an avalanche photodiode. As depicted in FIG. 8, the pixel 250 includes an N-type first semiconductor region 201, a P-type second semiconductor region 202 provided below the N-type first semiconductor region 201, and a well layer 203. The N-type first semiconductor region 201 and the P-type second semiconductor region 202 are provided in the well 203 layer.

The well layer 203 may be a P-type semiconductor region. Furthermore, the well layer 203 may be, for example, a low-concentration semiconductor region having a P-type impurity concentration of smaller than 1×10¹⁵ cm⁻³. Therefore, the well layer 203 may be easily depleted, and detection efficiency referred to as photon detection efficiency (PDE) may be improved.

The N-type first semiconductor region 201 includes, for example, N-type silicon (Si). The P-type second semiconductor region 202 includes, for example, P-type silicon (Si). A portion in which the N-type first semiconductor region 201 and the P-type second semiconductor region 202 are in contact with each other is a PN junction of the avalanche photodiode. A carrier generated by light incident on the sensor substrate 1B is subjected to avalanche amplification at the PN junction described above. The P-type second semiconductor region 202 is preferably depleted, whereby the PDE may be improved.

The N-type first semiconductor region 201 serves as, for example, a cathode and is connected to a circuit via a contact electrode 204. An anode electrode 205 is provided continuously between the N-type first semiconductor region 201 and an isolation region 208, between the well layer 203 and the isolation region 208, and below the well layer 203 (a back surface side of the pixel 250). The anode electrode 205 is connected to a bias circuit via a contact electrode 206.

The anode electrode 205 includes, similarly to the anode electrode 21 described in the first embodiment, for example, P-type amorphous silicon carbide (a-SiC), P-type polysilicon carbide (poly-SiC), P-type amorphous silicon nitride (a-SiN), or P-type polysilicon nitride (poly-SiN).

The sensor substrate 1B may be applied to a back-illuminated imaging device or a front-illuminated imaging device. In a case where the sensor substrate 1B is applied to the back-illuminated imaging device, a lens body such as a microlens is stacked under the well layer 203 (on a side opposite to a side on which the N-type first semiconductor region 201 is formed).

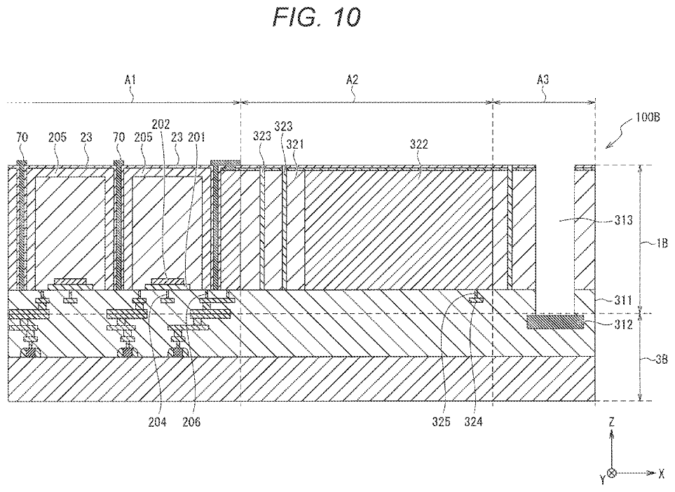

Furthermore, in a case where the sensor substrate 1B is applied to the back-illuminated imaging device, a lens body such as a microlens is stacked on an upper surface (a surface on which the N-type first semiconductor region 201 is formed) side of the well layer 203 via a logic substrate 3B (refer to FIG. 10 below) or the like.

The isolation region 208 is a region for isolating the adjacent pixels 250 from each other, and includes, for example, a silicon oxide film. The isolation region 208 may be formed so as to penetrate from the upper surface side to a lower surface side of the well layer 203 as depicted in FIG. 8, or may be formed so as to penetrate only a part from the upper surface side to the lower surface side of the well layer 203.

FIG. 9 is a plan view schematically depicting a configuration example of an imaging device 100B according to the second embodiment of the present disclosure. FIG. 10 is a cross-sectional view depicting a configuration example of the imaging device 100B according to the second embodiment of the present disclosure. FIG. 10 depicts a cross section of the plan view depicted in FIG. 9 taken along line X9-X′9. As depicted in FIGS. 9 and 10, the plurality of pixels 250 is arranged in an array in a pixel region A1 provided on the sensor substrate 1B.

The logic substrate 3B is connected to the lower surface (a surface opposite to a light incident surface) of the sensor substrate 1B on which the plurality of pixels 250 is arranged. In the logic substrate 3B, a circuit that processes a signal from the pixel 250 and supplies power to the pixel 250 is formed.

A peripheral region A2 is arranged outside the pixel region A1. Moreover, a pad region A3 is arranged outside the peripheral region A2. As depicted in FIG. 10, the pad region A3 is a hole in a vertical direction extending from an upper end of the sensor substrate 1B to the inside of a wiring layer 311, and pad openings 313, which are holes for wiring to electrode pads 312, are formed so as to be aligned in a straight line.

The electrode pad 312 for wiring is provided at a bottom of the pad opening 313. The electrode pad 312 is used, for example, when being connected to a wire in the wiring layer 311 or connected to another external device (chip or the like). Furthermore, a wiring layer close to a bonding surface between the sensor substrate 1B and the logic substrate 3B may also serve as the electrode pad 312.

The wiring layer 311 formed in the sensor substrate 1B and the wiring layer formed in the logic substrate 3B each includes an insulating film and a plurality of wires, and the plurality of wires and the electrode pads 312 are formed using metal such as copper (Cu) or aluminum (Al), for example. The wires formed in the pixel region A1 and the peripheral region A2 are also formed using a similar material.

The peripheral region A2 is provided between the pixel region A1 and the pad region A3. The peripheral region A2 includes a ring-shaped N-type semiconductor region 321 surrounding the pixel region A1 in plan view and a ring-shaped P-type semiconductor region 322 surrounding the pixel region A1 outside the N-type semiconductor region 321 in plan view. A side surface on an outer peripheral side of the N-type semiconductor region 321 is in contact with a side surface on an inner peripheral side of the P-type semiconductor region 322. Furthermore, the P-type semiconductor region 322 is connected to the wiring layer 324 via the contact electrode 325, and the wiring layer 324 is connected to ground (GND).

In the example depicted in FIG. 10, in the pixel region A1, the sensor substrate 1B and the logic substrate 3B are electrically connected to each other in such a manner that a part of the wiring layer located the closest to a bonding surface side out of the wiring layers formed on the bonding surface side of the sensor substrate 1B and of the logic substrate 3B are directly joined to each other.

In the N-type semiconductor region 321, for example, two trenches 323 are formed. The trenches 323 are provided to physically isolate the pixel region A1 from the peripheral region A2. FIG. 10 depicts a case where the two trenches 323 are formed, but the number of trenches 323 formed may be one or three or larger.

In the pixel region A1, a high voltage is applied between the first semiconductor region 201 (cathode) and the anode electrode 205 in the plurality of pixels 250. Furthermore, the peripheral region A2 is grounded to GND. In the isolation region between the pixel region A1 and the peripheral region A2, a high electric field region is generated due to application of a high voltage to the anode electrode 205, and breakdown might occur. In order to avoid the breakdown, it is conceivable to expand the isolation region between the pixel region A1 and the peripheral region A2, but the sensor substrate 1B becomes large by expanding the isolation region.

In the second embodiment of the present disclosure, the trench 323 is formed in order to suppress the occurrence of breakdown in the isolation region between the pixel region A1 and the peripheral region A2. The breakdown may be suppressed by the trench 323 without expanding the isolation region.

As described above, the sensor substrate 1B according to the second embodiment of the present disclosure includes the N-type first semiconductor region 201, the P-type second semiconductor region 202 in contact with one surface of the first semiconductor region 201, the well layer 203 (an example of a “light absorbing region” in the present disclosure) provided on a side opposite to the first semiconductor region 201 across the second semiconductor region 202, and the anode electrode 205 provided at a position facing the second semiconductor region 12 across the well layer 203. The anode electrode 205 includes a P-type semiconductor (for example, P-type a-SiC, P-type poly-SiC, P-type a-SiN, or P-type poly-SiN) having a refractive index of 1.8 or larger and an optical bandgap of 1.9 eV or larger.

With this, the anode electrode 205 may be formed by a CVD method, and the P-type impurity concentration in the film may be made uniform or substantially uniform. Therefore, the imaging device including the sensor substrate 1B has an effect similar to that of the first embodiment described above.

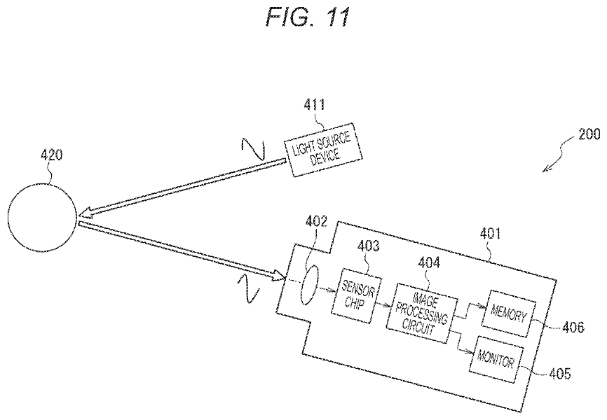

Note that, the configurations of the peripheral region A2 and the pad region A3 depicted in FIGS. 10 and 11 are also applicable to the first embodiment. For example, in FIGS. 10 and 11, the pixel 250 may be replaced with the pixel 50 depicted in FIG. 1 or 7.

### Third Embodiment

FIG. 11 is a block diagram depicting a configuration example of a ranging device 200 according to a third embodiment of the present disclosure. As depicted in FIG. 11, a ranging device 200 (an example of an “electronic device” of the present disclosure) includes a distance image sensor 401 and a light source device 411 (an example of a “light source” of the present disclosure). The light source device 411 emits light of a wavelength band set in advance (for example, infrared light).

The distance image sensor 401 includes an optical system 402, a sensor chip 403, an image processing circuit 404, a monitor 405, and a memory 406. Then, the distance image sensor 401 may obtain a distance image according to a distance to a subject 420 by receiving light (modulated light or pulsed light) projected from the light source device 411 toward the subject 420 and reflected on a surface of the subject 420.

The optical system 402 including one or a plurality of lenses guides image light from the subject 420 (incident light) to a sensor chip 403 to form an image on a light-receiving surface (sensor unit) of the sensor chip 403.

The sensor chip 403 photoelectrically converts infrared light and outputs a signal. For example, a light reception signal (APD OUT) is output from the sensor chip 403. A distance signal indicating a distance acquired from the output light reception signal is supplied to the image processing circuit 404. Note that, the imaging device 100 of the first embodiment or the imaging device 100B of the second embodiment described above is applied as the sensor chip 403.

The image processing circuit 404 performs image processing of constructing the distance image on the basis of the distance signal supplied from the sensor chip 403, and the distance image (image data) obtained by the image processing is supplied to and displayed on the monitor 405, or supplied to and stored (recorded) in the memory 406.

In the distance image sensor 401 configured in this manner, an imaging characteristic may be improved by applying the above-described imaging devices 100 and 100B, and for example, a more accurate distance image may be obtained.

### Other Embodiment

As described above, the present disclosure is described according to the embodiments and variations thereof, but it should not be understood that the description and drawings forming a part of this disclosure limit the present disclosure. Various alternative embodiments, examples, and operation techniques will be apparent to those skilled in the art from this disclosure. For example, in the embodiment of the present disclosure, light to be detected is not limited to infrared light. The light to be detected may be, for example, visible light having a wavelength band of 400 nm or longer and 650 nm or shorter. As described above, it is a matter of course that the present technology includes various embodiments and the like not described herein. At least one of various omissions, substitutions, and changes of the components may be made without departing from the gist of the above-described embodiments and variations. Furthermore, the effect described in this specification is illustrative only; the effect is not limited thereto and there may also be another effect.

### Application Example to Endoscopic Surgery System

The technology according to an embodiment of the present disclosure (present technology) is applicable to various products. For example, the technology according to an embodiment of the present disclosure may be applied to an endoscopic surgery system.

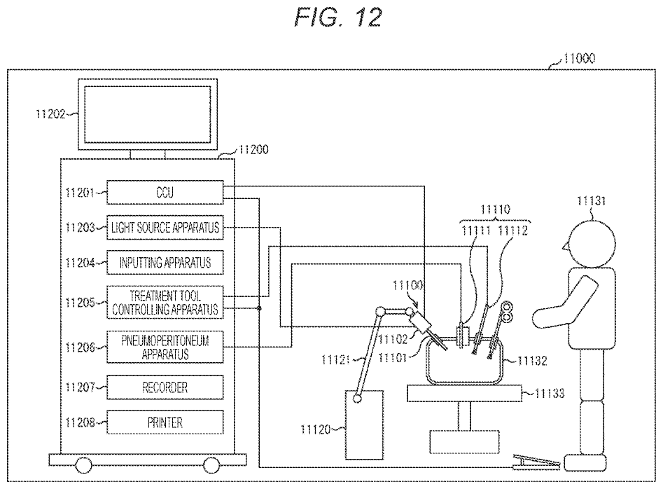

FIG. 12 is a view depicting an example of a schematic configuration of an endoscopic surgery system to which the technology according to an embodiment of the present disclosure (present technology) can be applied.

In FIG. 12, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

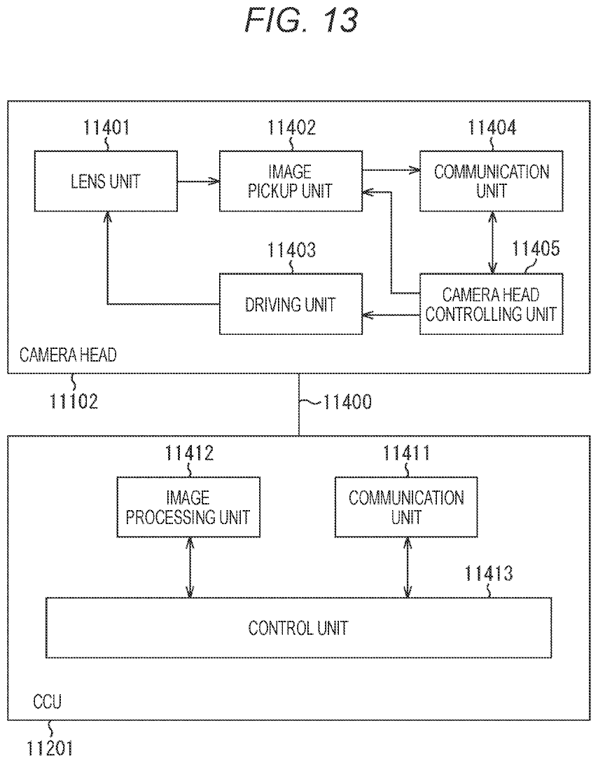

FIG. 13 is a block diagram depicting an example of a functional configuration of the camera head 11102 and the CCU 11201 depicted in FIG. 12.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to an embodiment of the present disclosure can be applied is described above. The technology according to an embodiment of the present disclosure can be applied to the endoscope 11100, (the image pickup unit 11402 of) the camera head 11102, (the image processing unit 11412 of) the CCU 11201, and the like, for example, out of the configurations described above. Specifically, the imaging device 100 depicted in FIG. 1, the imaging device 100B depicted in FIG. 9, or the sensor substrate 1 depicted in FIG. 1, the sensor substrate 1A depicted in FIG. 7, and the sensor substrate 1B depicted in FIG. 8 can be applied to the image pickup unit 10402. By applying the technology according to an embodiment of the present disclosure to the endoscope 11100, the image pickup unit 11402 of the camera head 11102, the image processing unit 11412 of the CCU 11201, and the like, for example, variation in sensitivity between a plurality of pixels is reduced, and a clearer surgical region image can be obtained, so that the operator can reliably confirm the surgical region.

Note that, the endoscopic surgery system is herein described as an example, but in addition to this, the technology according to an embodiment of the present disclosure may also be applied to a microscopic surgery system and the like, for example.

### Application Example to Mobile Body

The technology according to an embodiment of the present disclosure (present technology) is applicable to various products. For example, the technology according to an embodiment of the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

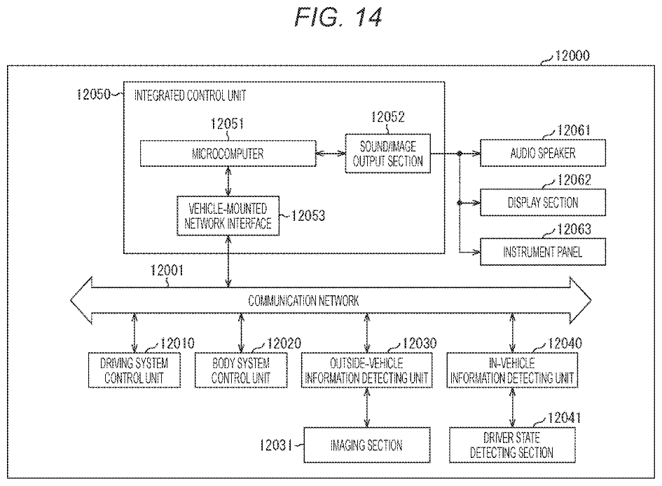

FIG. 14 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 14, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 may output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are illustrated as the output device. The display section 12062 may, for example, include at least one of an on-board display and a head-up display.

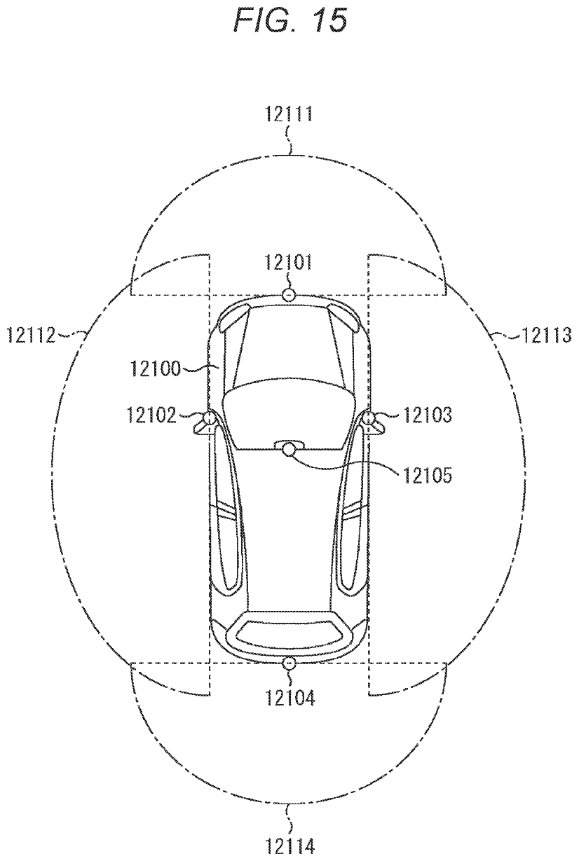

FIG. 15 is a diagram depicting an example of the installation position of the imaging section 12031.

In FIG. 15, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The images of the front obtained by the imaging sections 12101 and 12105 are used mainly to detect a preceding vehicle, a pedestrian, an obstacle, a signal, a traffic sign, a lane, or the like.

Incidentally, FIG. 15 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure can be applied is described above. The technology according to an embodiment of the present disclosure can be applied to the imaging section 12031 and the like out of the configurations described above. Specifically, the imaging device 100 depicted in FIG. 1, the imaging device 100B depicted in FIG. 9, or the sensor substrate 1 depicted in FIG. 1, the sensor substrate 1A depicted in FIG. 7, and the sensor substrate 1B depicted in FIG. 8 can be applied to the imaging section 12031. By applying the technology according to an embodiment of the present disclosure, for example, variation in sensitivity between a plurality of pixels is reduced, and a more easily viewable taken image may be obtained, so that driver's fatigue may be reduced.

Note that, the present disclosure may also have the following configuration.

(1)

An imaging device provided with:
an N-type first semiconductor region;
a P-type second semiconductor region in contact with one surface of the first semiconductor region;
a light absorbing region provided on a side opposite to the first semiconductor region across the second semiconductor region; and
an anode electrode provided at a position facing the second semiconductor region across the light absorbing region, in which
the anode electrode includes a P-type semiconductor having a refractive index of 1.8 or larger and an optical bandgap of 1.9 eV or larger.

(2)

The imaging device according to (1) described above, in which
the anode electrode includes:
a first site facing the second semiconductor region in a thickness direction of the light absorbing region; and
a second site facing the second semiconductor region in a direction intersecting the thickness direction of the light absorbing region.

(3)

The imaging device according to (1) or (2) described above, in which the anode electrode includes P-type amorphous silicon carbide, P-type polysilicon carbide, P-type amorphous silicon nitride, or P-type polysilicon nitride.

(4)

The imaging device according to any one of (1) to (3) described above, in which a boron concentration in the anode electrode is 1×10¹⁸ cm⁻³ or larger.

(5)

The imaging device according to any one of (1) to (4) described above, further provided with: an insulating film provided on a side opposite to the light absorbing region across the anode electrode, the insulating film having a refractive index lower than the refractive index of the anode electrode.

(6)

The imaging device according to (5) described above, in which the insulating film is an aluminum oxide film, a silicon oxide film, or a hafnium oxide film.

(7)

The imaging device according to (5) or (6) described above, further provided with: a lens body provided on a side opposite to the light absorbing region across the insulating film in a thickness direction of the light absorbing region.

(8)

The imaging device according to any one of (1) to (7) described above, in which a voltage for electron amplification is applied between the anode electrode and the first semiconductor region.

(9)

The imaging device according to any one of (1) to (8) described above, provided with:
a semiconductor substrate;
a plurality of pixels provided on the semiconductor substrate; and
a light-shielding pixel isolation unit that is provided on the semiconductor substrate and isolates adjacent pixels among the plurality of pixels from each other, in which
the first semiconductor region, the second semiconductor region, the light absorbing region, and the anode electrode are arranged in each of the plurality of pixels.

(10)

An electronic device provided with:
a light source that emits light of a wavelength band set in advance; and
an imaging device that photoelectrically converts the light and outputs a signal, in which
the imaging device is provided with:
an N-type first semiconductor region;
a P-type second semiconductor region in contact with one surface of the first semiconductor region;
a light absorbing region provided on a side opposite to the first semiconductor region across the second semiconductor region; and
an anode electrode provided at a position facing the second semiconductor region across the light absorbing region, and
the anode electrode includes a P-type semiconductor having a refractive index of 1.8 or larger and an optical bandgap of 1.9 eV or larger.

### REFERENCE SIGNS LIST

1, 1A, 1B Sensor substrate
1a, 10a, 30a Front surface
3, 3B Logic substrate
10, 30 Semiconductor substrate
10b Back surface
11, 201 First semiconductor region
11a Other surface
11b One surface
12, 202 Second semiconductor region
13 Third semiconductor region
14 Fourth semiconductor region
15 Fifth semiconductor region
16 Sixth semiconductor region
17 Seventh semiconductor region
18 Eighth semiconductor region
19, 39 Interlayer insulating film
21, 205 Anode electrode
23 First insulating film
25 Second insulating film
50, 250 Pixel
70 Metal film
70 Light-shielding electrode
80 Microlens
100, 100B Imaging device
200 Ranging device
203 Well layer
204, 206, 325, CA, CE, CGND, CK Contact electrode
208 Isolation region
211 First site
212 Second site
311, 324, ML11, ML12, ML31, ML32, ML33 Wiring layer
312 Electrode pad
313 Pad opening
321 N-type semiconductor region
322 P-type semiconductor region
323, H1 Trench
401 Distance image sensor
402 Optical system
403 Sensor chip
404 Image processing circuit
405 Monitor
406 Memory
411 Light source device
420 Subject
10402 Image pickup unit
11000 Endoscopic surgery system
11100 Endoscope
11101 Lens barrel
11102 Camera head
11110 Surgical tool
11111 Pneumoperitoneum tube
11112 Energy device
11120 Supporting arm apparatus
11131 Surgeon
11132 Patient
11133 Patient bed
11200 Cart
11202 Display apparatus
11203 Light source apparatus
11204 Inputting apparatus
11205 Treatment tool controlling apparatus
11206 Pneumoperitoneum apparatus
11207 Recorder
11208 Printer
11400 Transmission cable
11401 Lens unit
11402 Image pickup unit
11403 Driving unit
11404 Communication unit
11405 Camera head controlling unit
11411 Communication unit
11412 Image processing unit
11413 Control unit
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101, 12102, 12103, 12104, 12105 Imaging section
12111, 12112, 12113, 12114 Imaging range
A1 Pixel region
A2 Peripheral region
A3 Pad region
CF Color filter
CF-B Blue filter
CF-G Green filter
CF-R Red filter
RP1, RP2 Resist pattern
TrN MOS transistor
TrP MOS transistor

1. An imaging device comprising:
an N-type first semiconductor region;
a P-type second semiconductor region in contact with one surface of the first semiconductor region;
a light absorbing region provided on a side opposite to the first semiconductor region across the second semiconductor region; and
an anode electrode provided at a position facing the second semiconductor region across the light absorbing region, wherein
the anode electrode includes a P-type semiconductor having a refractive index of 1.8 or larger and an optical bandgap of 1.9 eV or larger.

2. The imaging device according to claim 1, wherein
the anode electrode includes:
a first site facing the second semiconductor region in a thickness direction of the light absorbing region; and
a second site facing the second semiconductor region in a direction intersecting the thickness direction of the light absorbing region.

3. The imaging device according to claim 1, wherein the anode electrode includes P-type amorphous silicon carbide, P-type polysilicon carbide, P-type amorphous silicon nitride, or P-type polysilicon nitride.

4. The imaging device according to claim 1, wherein a boron concentration in the anode electrode is 1×10¹⁸ cm⁻³ or larger.

5. The imaging device according to claim 1, further comprising: an insulating film provided on a side opposite to the light absorbing region across the anode electrode, the insulating film having a refractive index lower than the refractive index of the anode electrode.

6. The imaging device according to claim 5, wherein the insulating film is an aluminum oxide film, a silicon oxide film, or a hafnium oxide film.

7. The imaging device according to claim 5, further comprising: a lens body provided on a side opposite to the light absorbing region across the insulating film in a thickness direction of the light absorbing region.

8. The imaging device according to claim 1, wherein a voltage for electron amplification is applied between the anode electrode and the first semiconductor region.

9. The imaging device according to claim 1, further comprising:
a semiconductor substrate;
a plurality of pixels provided on the semiconductor substrate; and
a light-shielding pixel isolation unit that is provided on the semiconductor substrate and isolates adjacent pixels among the plurality of pixels from each other, wherein
the first semiconductor region, the second semiconductor region, the light absorbing region, and the anode electrode are arranged in each of the plurality of pixels.

10. An electronic device comprising:
a light source that emits light of a wavelength band set in advance; and
an imaging device that photoelectrically converts the light and outputs a signal, wherein
the imaging device is provided with:
an N-type first semiconductor region;
a P-type second semiconductor region in contact with one surface of the first semiconductor region;
a light absorbing region provided on a side opposite to the first semiconductor region across the second semiconductor region; and
an anode electrode provided at a position facing the second semiconductor region across the light absorbing region, and
the anode electrode includes a P-type semiconductor having a refractive index of 1.8 or larger and an optical bandgap of 1.9 eV or larger.
